(19) United States
(12) Patent Application Publication
(10) Pub. No.: US 2011/0019369 A1
(43) Pub. Date: Jan. 27, 2011

(54) ELECTRONIC CIRCUIT MODULE WITH GOOD HEAT DISSIPATION

(76) Inventors: Takeshi Kanno, Niigata-Ken (JP); Satoshi Oura, Niigata-Ken (JP)

Correspondence Address: BRINKS HOFER GILSON & LIONE, P.O. BOX 10395, CHICAGO, IL, 60610, US

(21) Appl. No.: 12/839,908

(22) Filed: Jul. 20, 2010

(30) Foreign Application Priority Data
Jul. 21, 2009 (JP) 2009-169867

(51) Int. Cl. H05K 7/00

(52) U.S. Cl. 361/748

(57) ABSTRACT

An electronic circuit module includes a circuit board provided with the connector section, electronic parts provided on a mounting surface of the circuit board, a metallic board provided with a bonding section, which is superimposed on a part of the mounting surface of the circuit board, and an extension section which extends from the circuit board and is formed with the fixing through holes, a connection member that connects the circuit board to the metallic board, and a shim member superimposed at the same side as the circuit board with respect to the extension section of the metallic board, and having a thickness substantially identical to a thickness of the circuit board.

### CROSS REFERENCE TO RELATED APPLICATION

The present invention contains subject matter related to and claims priority to Japanese Patent Application JP 2009-169867 filed in the Japanese Patent Office on Jul. 21, 2009, the entire content of which is incorporated herein by reference.

### BACKGROUND

1. Technical Field

The present disclosure relates to an electronic circuit module.

2. Related Art

An electronic circuit module, in which electronic parts such as an IC chip are mounted on a board, has various functions. For example, a wireless LAN module is installed inside of a portable apparatus such as a personal computer.

Further, the electronic circuit module has various standards for the shape and dimension thereof in association with installation to an external apparatus. For example, in a full-mini card and a half-mini card of a PCI Express (PCIe), a connector section connected to the external apparatus is formed at one end of a circuit board constituting the electronic circuit module, and through holes for screwing to the external apparatus are formed at the other end thereof.

Meanwhile, in the electronic circuit module, electrical properties of electronic parts vary depending on heat generated in the electronic parts, so that, in the worst case, the electronic parts may be damaged. In this regard, the electronic circuit module is provided with a heat dissipation plate, as with a cooling apparatus disclosed in Japanese Unexamined Patent Application Publication No. 5-315713.

As with the cooling apparatus disclosed in Japanese Unexamined Patent Application Publication No. 5-315713, when the heat dissipation plate is installed in an upright position with respect to the board, the height of the electronic circuit module may increase. Since an external apparatus has a limitation in the height of the electronic circuit module which can be installed therein, an increase in the height of the electronic circuit module is not desired.

Meanwhile, integration of electronic parts has been performed with the improvement of a miniaturization technology. According to an existing technology, for example, even in the case of the electronic circuit module with the necessity of using a circuit board having a dimension of a full-mini card of a PCIe, it is possible to constitute the electronic circuit module by using a circuit board having a dimension of a half-mini card corresponding to the half of the full-mini card.

In such a case, in order to improve the general versatility by unifying the specifications of the circuit board, it is preferred to replace the full-mini card of the PCIe with the half-mini card if possible.

Further, the manufacturing cost of the circuit board increases in proportion to the area thereof. This tendency is particularly noticeable in a circuit board formed using a build-up process. In this regard, it is preferred to replace the full-mini card of the PCIe with the half-mini card if possible.

However, when an installation section of the electronic circuit module in an external apparatus corresponds only to the full-mini card of the PCIe, if the half-mini card of the PCIe is installed, the length of the circuit board is not sufficient and thus the circuit board may not be screwed. Therefore, the electronic circuit module may not be firmly fixed to the external apparatus, resulting in a degradation of reliability.

### SUMMARY

According to one embodiment of the invention, there is provided an electronic circuit module with good heat dissipation, which has a connector section to be inserted into an external apparatus and is formed with fixing through holes for screwing to the external apparatus, the electronic circuit module including: a circuit board provided with the connector section; electronic parts provided on a mounting surface of the circuit board; a metallic board provided with a bonding section, which is superimposed on a part of the mounting surface of the circuit board, and an extension section which extends from the circuit board and is formed with the fixing through holes; a connection member that connects the circuit board to the metallic board; and a shim member superimposed at the same side as the circuit board with respect to the extension section of the metallic board, and having a thickness substantially identical to a thickness of the circuit board.

In another embodiment, the electronic circuit module further includes a metallic cover that covers at least a part of the electronic parts.

As described above, according to the present invention, it is possible to provide a small electronic circuit module with good heat dissipation by using a circuit board with a high general versatility.

### BRIEF DESCRIPTION OF THE DRAWINGS

FIG. 1 is a perspective view schematically illustrating an external appearance of a personal computer to which an electronic circuit module according to one embodiment is applied.

FIG. 2 is a perspective view schematically illustrating an electronic circuit module of one embodiment and an installation structure of an external apparatus.

FIG. 3 is a sectional view schematically illustrating a longitudinal section of an electronic circuit module of FIG. 2 installed in an external apparatus.

FIG. 4 is an exploded perspective view schematically illustrating an electronic circuit module of FIG. 2.

FIG. 5 is a diagram illustrating a manufacturing method of a shim member used for an electronic circuit module of FIG. 2.

### DESCRIPTION OF EXEMPLARY EMBODIMENTS

Hereinafter, embodiments of the invention will be described with reference to the accompanying drawings. For the purpose of convenience, the positions, sizes and the like of members are appropriately emphasized and drawn in the accompanying drawings.

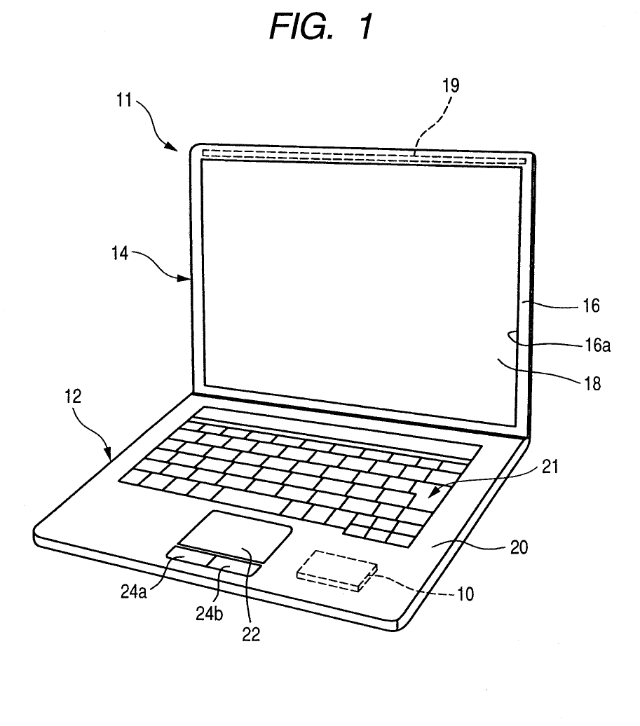

FIG. 1 is a perspective view illustrating a laptop personal computer (electronic apparatus) 11 provided with an electronic circuit module 10 according to one embodiment. The computer 11 includes a body 12 and a display 14, and the body 12 and the display 14 are connected to each other through a hinge.

The display 14, for example, includes a display housing 16 made of resin. The display housing 16 has a flat box shape and, for example, has a size approximately equal to that of A4 paper. An opening 16a is formed throughout almost all of the region of a surface of the display housing 16, which is located to a side of the body 12. A liquid crystal panel 18 is exposed through the opening 16a of the display housing 16.

Further, the display housing 16 has an antenna 19 for radio communication therein.

The body 12 includes a main housing 20 made of resin and having a flat box shape.

The main housing 20 is provided with a keyboard 21 on the innermost side of the upper surface thereof when viewed toward the liquid crystal panel 18, and a touch pad 22 and buttons 24a and 24b are arranged in front of the keyboard 21.

The electronic circuit module 10 is embedded in the body 12, and, for example, is a UWB (Ultra WideBand) wireless module having a function of transmitting and receiving a high frequency wave.

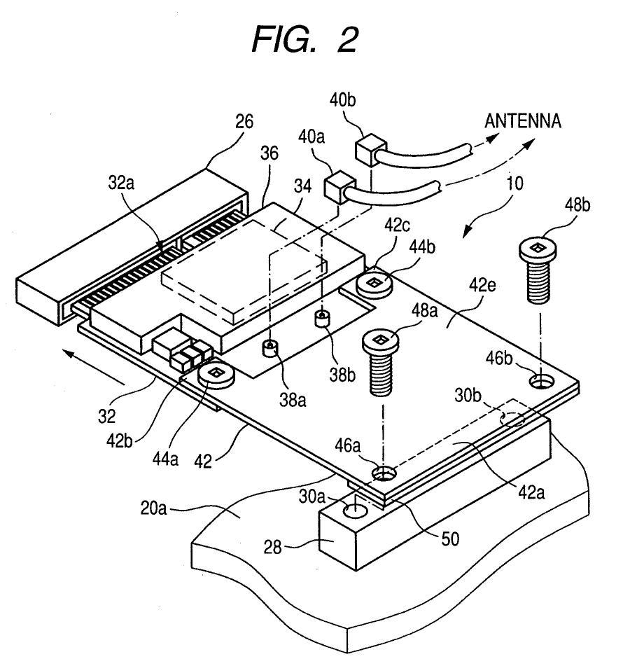

FIG. 2 is a diagram illustrating the electronic circuit module 10 and an installation structure of the electronic circuit module 10 with respect to the body 12.

A slot 26 is tiltably installed with respect to a lower wall 20a of the main housing 20, and a mount section 28 is integrally formed with the lower wall 20a to protrude from the lower wall 20a by a predetermined height. The mount section 28 is formed with two screw holes 30a and 30b.

In addition, the electronic circuit module 10, for example, conforms to a PCI Express (PCIe) full-mini size standard, and the sizes, shapes and arrangement of the slot 26, the mount section 28 and the screw holes 30a and 30b also conform to the PCIe full-mini size standard.

The electronic circuit module 10 includes a printed circuit board 32 having a wiring pattern.

The printed circuit board 32, for example, is a multi-layer board formed using a build-up process. The size of the printed circuit board 32 conforms to the PCIe half-mini size standard.

A connector section 32a is integrally formed with one side of the printed circuit board 32 located at one end in the longitudinal direction of the electronic circuit module 10. The connector section 32a is provided with a plurality of electrodes. If the connector section 32a is inserted into the slot 26, an electrical signal and power are exchanged between the body 12 and the electronic circuit module 10 through the electrodes of the connector section 32a.

Further, the electronic circuit module 10 includes a plurality of electronic parts mounted on one surface (mounting surface) of the printed circuit board 32. For example, the printed circuit board 32 is provided with an IC chip 34 for high frequency radio and the like as electronic parts.

Preferably, the printed circuit board 32 is provided on the mounting surface thereof with a metallic cover 36 having a box shape. The cover 36 is arranged to cover at least a part of the electronic parts such as the IC chip 34 on the mounting surface, thereby protecting the electronic parts mechanically and electrically.

In addition, the printed circuit board 32 is provided on the mounting surface thereof with two antenna connection terminals 38a and 38b. The antenna connection terminals 38a and 38b are connected to two antenna cables 40a and 40b, which are provided in the body 12, respectively. The electronic circuit module 10 is connected to an antenna 19 through the antenna cables 40a and 40b.

Moreover, the electronic circuit module 10 includes a metallic board 42. The metallic board 42, for example, includes a flat plate made of metal such as copper and aluminum. The metallic board 42 is connected to the printed circuit board 32 by using two connection screws 44a and 44b.

The size of the metallic board 42 is set such that the external appearance shapes of the printed circuit board 32 and the metallic board 42 conform to the PCIe full-mini size standard when viewed in a plan view.

The metallic board 42, which is located at an opposite side of the printed circuit board 32, is formed at an end portion (fixed end portion) 42a thereof with two fixing through holes 46a and 46b which are spaced apart from each other in the width direction of the electronic circuit module 10. The sizes and the positions of these fixing through holes 46a and 46b are set to conform to the PCIe full-mini size standard.

If the connector section 32a is inserted into the slot 26, the fixing through holes 46a and 46b communicate with the screw holes 30a and 30b of the mount section 28, respectively. Then, fixing screws 48a and 48b are screwed into the fixing through holes 46a and 46b and the screw holes 30a and 30b, which communicate with each other, so that the electronic circuit module 10 is fixed to the lower wall 20a of the main housing 20.

In addition, a shim member 50 is interposed between the fixed end portion 42a of the metallic board 42 and the mount section 28. The shim member 50 has a thickness substantially identical to that of the printed circuit board 32. Moreover, the fact that the thickness and the interval are substantially the same represents that the difference of the thickness and the interval exists in the range of tolerance.

The shim member 50 may bond to the metallic board 42 by using an adhesive and the like, or may also be provided separately from the metallic board 42.

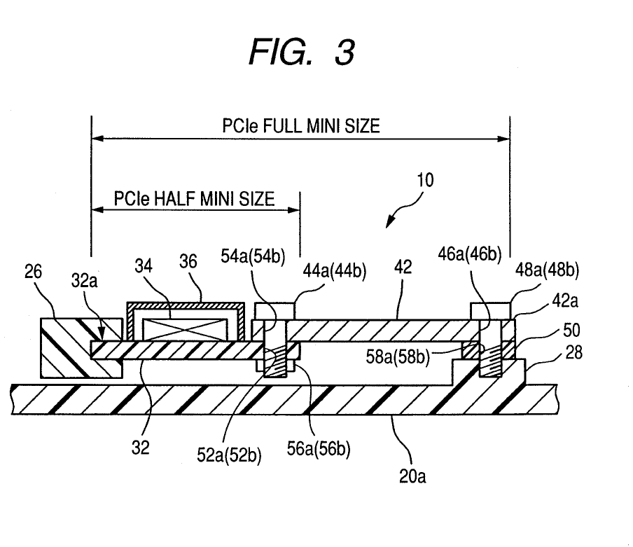

FIG. 3 is a sectional view schematically illustrating a longitudinal section of the electronic circuit module 10 installed in the main housing 20.

As shown in FIG. 3, the printed circuit board 32 and the metallic board 42 are formed with circuit board through holes 52a and 52b and connection through holes 54a and 54b, through which the connection screws 44a and 44b are inserted, respectively.

Nuts 56a and 56b are screwed onto the front end of the connection screws 44a and 44b, and the connection screws 44a and 44b cooperate with the nuts 56a and 56b, so that the printed circuit board 32 and the metallic board 42 are connected to each other.

Further, the shim member 50 is also formed with through holes 58a and 58b through which the fixing screws 48a and 48b are inserted.

Herein, as shown in FIG. 3, when viewed in the longitudinal direction of the electronic circuit module 10, the length from the front end of the connector section 32a to the other end of the printed circuit board 32 conforms to the PCIe half-mini size standard. Further, the length from the front end of the connector section 32a to an end of the metallic board 42, which is located at the fixed end portion 42a, conforms to the PCIe full-mini size standard. That is, it can be said that the printed circuit board 32 and the metallic board 42 bonding to each other constitutes a single board conforming to the PCIe full-mini size standard.

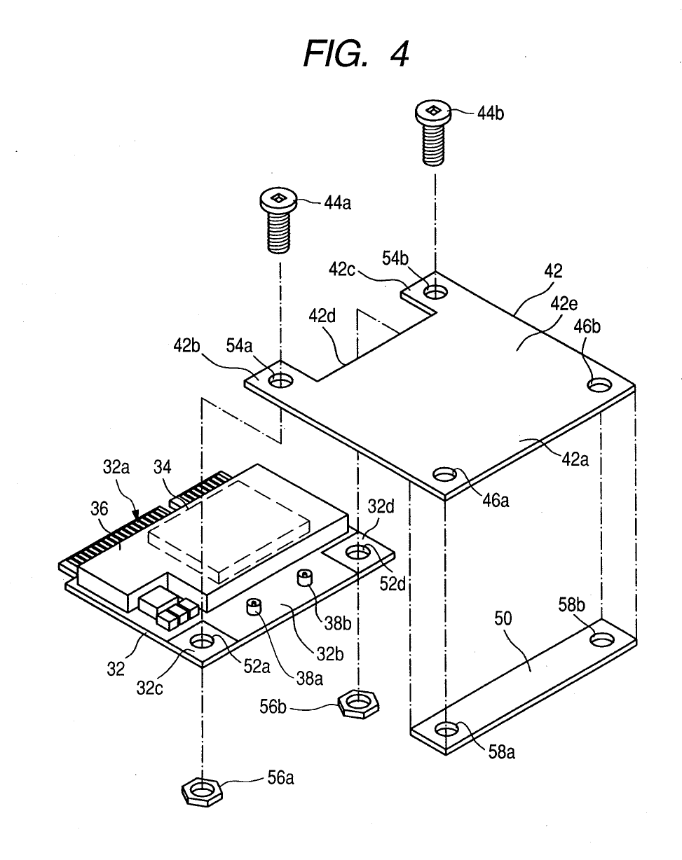

FIG. 4 is an exploded perspective view schematically illustrating the electronic circuit module 10. As shown in FIG. 4, bonding sections 42b and 42c of the metallic board 42, which is superimposed on the printed circuit board 32, have a rectangular shape when viewed in a plan view, and the bonding sections 42b and 42c are formed at the center thereof with the connection through holes 54a and 54b, respectively. A notched section 42d having a rectangular shape when viewed in a plan view is formed between the bonding sections 42b and 42c.

In this regard, it can be said that the metallic board 42 has a rectangular extension section 42e and the bonding sections 42b and 42c, which extend from the printed circuit board 32.

The antenna connection terminals 38a and 38b are formed on an exposure region 32b of the printed circuit board 32 exposed to the notched section 42d. In addition, the exposure region 32b is not covered by the cover 36.

In the printed circuit board 32, lands 32c and 32d including conductors are formed on regions (sections to be bonded) on which the bonding sections 42b and 42c are superimposed, and the lands 32c and 32d are connected to a ground layer in the printed circuit board 32. The circuit board through holes 52a and 52b are opened in the center of the lands 32c and 32d, respectively.

The exposure region 32b, on which the antenna connection terminals 38a and 38b are installed, is located between the lands 32c and 32d, and the exposure region 32b and the lands 32c and 32d are located at an opposite side of the connector section 32a.

An interval between the circuit board through holes 52a and 52b conforms to the PCIe half-mini size standard, and an interval between the connection through holes 54a and 54b, which communicate with the circuit board through holes 52a and 52b, also conform to the PCIe half-mini size standard.

Further, an interval between the fixing through holes 46a and 46b and an interval between the through holes 58a and 58b conform to the PCIe full-mini size standard.

Herein, since intervals among the through holes for screwing and fixing are equal to each other in the PCIe half-mini size standard and the PCIe full-mini size standard, the interval between the circuit board through holes 52a and 52b is substantially identical to the interval between the fixing through holes 46a and 46b.

The above-described electronic circuit module 10 can be manufactured using a well-known method. However, it is preferred to use a guide, which is obtained by cutting the printed circuit board 32, as a material for the shim member 50.

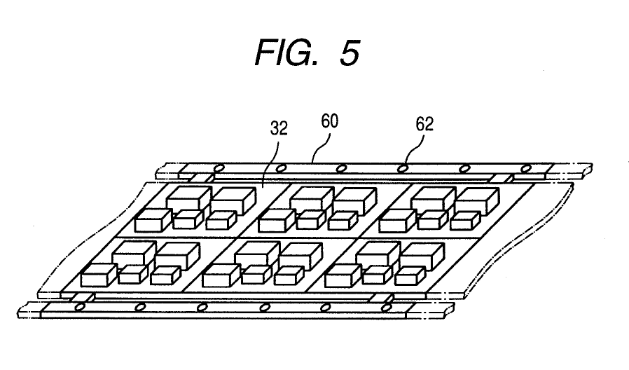

FIG. 5 is a diagram schematically illustrating the guide 60. The guide 60 is integrally formed with the printed circuit board 32. Since the guide 60 is manufactured in the same process as the printed circuit board 32, the guide 60 has a thickness substantially identical to that of the printed circuit board 32.

The guide 60 is formed with a plurality of guide holes 62 engaged with protrusions of a tractor provided in a reflow apparatus. In the state in which the protrusions are engaged with the guide holes 62, the tractor moves the guide 60 and the printed circuit board 32 in the reflow apparatus. During the movement, solder applied to the mounting surface is heated and temporarily molten, so that the electronic parts are fixed to the printed circuit board 32. After the reflow process, the guide 60 is cut from the printed circuit board 32.

In the electronic circuit module 10 according to the above-described embodiment, the printed circuit board 32 and the metallic board 42, which are connected to each other, constitute a single board corresponding to the PCIe full-mini size standard as a whole.

In the electronic circuit module 10, since the metallic board 42 with good thermal conductivity as compared with the printed circuit board 32 is connected to the printed circuit board 32, heat generated in the electronic parts is transmitted to the metallic board 42 so as to be radiated. That is, the metallic board 42 serves as a heat sink. Thus, the electronic circuit module 10 has good heat dissipation.

Further, since the metallic board 42 is just superimposed on the printed circuit board 32, the electronic circuit module 10 has a small size due to limitation in an increase of the height of the electronic circuit module 10. Thus, the electronic circuit module 10 is embedded in an external apparatus without any problem in the height thereof, and the range of the external apparatus, in which the electronic circuit module 10 can be installed, becomes wide, resulting in the improvement of general versatility.

In addition, the shim member 50 is superimposed, so that the metallic board 42 is prevented from being unstably fixed to the external apparatus and the electronic circuit module 10 is firmly fixed to the external apparatus. As a result, no load is applied to the connector section 32a due to vibration and the like, and the electronic circuit module 10 has good reliability.

Meanwhile, in the electronic circuit module 10, as compared with the case in which an entire board is formed of a single printed circuit board, it is possible to use the printed circuit board 32 having a small size (half size), for example, a size corresponding to the half. The printed circuit board 32 having a half size can be used for an electronic circuit module conforming to the PCIe half-mini size standard, and the general versatility of the printed circuit board 32 constituting the electronic circuit module 10 is improved, resulting in the reduction in the manufacturing cost.

Further, when the printed circuit board 32 is a build-up board, the manufacturing cost is increased according to the board area. However, the size of the printed circuit board 32 becomes small, resulting in the reduction in the manufacturing cost.

Consequently, the electronic circuit module 10 is provided at a low price.

According to the electronic circuit module 10 of the above-described embodiment, at least a part of the electronic parts is covered by the metallic cover 36, so that the electronic parts are protected from an external noise and the electronic circuit module 10 stably operates. Further, the external apparatus provided with the electronic circuit module 10 is protected from a noise generated from the electronic parts and the operation of the external apparatus is also stable.

In addition, in the electronic circuit module 10 of the above-described embodiment, the interval between the connection through holes 54a and 54b of the metallic board 42 is substantially identical to the interval between the fixing through holes 46a and 46b, so that treatment of the printed circuit board 32 can be reduced, resulting in the facilitation of assembly thereof. The reason is as follows.

The intervals among the fixing through holes for screwing the electronic circuit module to the external apparatus are equal to each other in the PCIe full-mini size standard and the PCIe half-mini size standard. That is, even if standards are different from each other, a case may occur in which the intervals among the fixing through holes are equal to each other.

Thus, when using a printed circuit board having the PCIe half-mini size as the printed circuit board 32, the interval between the connection through holes 54a and 54b of the metallic board 42 is set to be substantially identical to the interval between the fixing through holes 46a and 46b, so that the connection through holes 54a and 54b can be allowed to communicate with the circuit board through holes 52a and 52b formed through the printed circuit board 32 for the PCIe half-mini size.

Consequently, in the electronic circuit module 10, even when using the printed circuit board 32 of other standards, there is no need of treatment of the printed circuit board 32 for connection to the metallic board 42, assembly is facilitated.

Further, the printed circuit board 32 is connected to the metallic board 42 by using the two connection screws 44a and 44b, so that the rigidity of the electronic circuit module 10 as a whole is ensured.

In addition, according to the electronic circuit module 10 of the above-described embodiment, the antenna connection terminals 38a and 38b are arranged on the exposure region 32b, so that it is possible to obtain the electronic circuit module 10 with a simple configuration without complicating the shape of the cover 36.

The present invention is not limited to the above-described one embodiment. That is, various modifications can be made.

For example, the standard of the electronic circuit module 10 is not limited to the PCIe mini size standard. That is, the electronic circuit module 10 may correspond to various standards. Further, the electronic circuit module 10 is not limited to the UWB communication module. For example, the electronic circuit module 10 may be a wireless LAN module and the like. In addition, the electronic circuit module 10 is not also limited to be used for the high frequency radio communication.

Moreover, the external apparatus, to which the electronic circuit module 10 is applied, is not limited to the personal computer 11. For example, the external apparatus may include a cell phone, a MID (Mobile Internet Device), a digital camera, portable game machine and the like. These apparatuses have employed an interface (e.g., the PCIe) used for the personal computer. However, from the standpoint of space saving, miniaturization and power saving, fanless external apparatuses with no cooling fan are provided. In this regard, a cooling structure requiring no cooling fan is necessary.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic circuit module, which has a connector section to be inserted into an external apparatus and is formed with fixing through holes for screwing to the external apparatus, the electronic circuit module comprising:
a circuit board provided with the connector section;
electronic parts provided on a mounting surface of the circuit board;
a metallic board provided with a bonding section, which is superimposed on a part of the mounting surface of the circuit board, and an extension section which extends from the circuit board and is formed with the fixing through holes;
a connection member that connects the circuit board to the metallic board; and
a shim member superimposed at the same side as the circuit board with respect to the extension section of the metallic board, and having a thickness substantially identical to a thickness of the circuit board.

2. The electronic circuit according to claim 1, further comprising a metallic cover that covers at least a part of the electronic parts.

3. The electronic circuit module according to claim 2, wherein a section to be bonded of the circuit board, on which the bonding section is superimposed, is located in a vicinity of an outer periphery of the circuit board located at an opposite side of the connector section, the metallic board is formed with the two fixing through holes, and the connection member includes:
two connection through holes formed through the metallic board while being spaced apart from each other at an interval which is substantially identical to an interval between fixing through holes;
circuit board through holes formed through the section to be bonded while communicating with the two connection through holes; and
connection screws that are inserted through the circuit board through holes and the connection through holes.

4. The electronic circuit module according to claim 3, wherein the electronic parts constitute a radio communication circuit, the metallic board is provided with a notched section formed between the connection through holes, the circuit board includes an exposure region exposed to the notched section and not being covered by the cover; and a connector for antenna connection is arranged on the exposure region.
